(19) United States
(12) Patent Application Publication
(10) Pub. No.: US 2026/0324366 A1
(43) Pub. Date: Oct. 15, 2026

(54) SEMICONDUCTOR DEVICE AND PARTITIONABILITY MONITORING METHOD THEREOF

(71) Applicant: SK hynix Inc., Gyeonggi-do (KR)

(72) Inventor: Heon Yong CHANG, Gyeonggi-do (KR)

(21) Appl. No.: 19/299,357

(22) Filed: Aug. 14, 2025

(30) Foreign Application Priority Data
Apr. 14, 2025 (KR) 10-2025-0047866

(51) Int. Cl. H10P 74/00; H10W 42/00

(52) U.S. Cl. CPC H10P 74/273; H10W 42/00

(57) ABSTRACT

A semiconductor device including a substrate including a chip region and a guard ring region outside and adjacent to the chip region; a ferry test pad disposed across the guard ring region and a scribe lane region continuously located from the guard ring region; a cell test pad disposed in the guard ring region and positioned on the ferry test pad; and a scribe lane test pad disposed in the scribe lane region and positioned on the ferry test pad.

### CROSS-REFERENCE TO RELATED APPLICATION

The present application claims priority under 35 U.S.C. 119(a) to Korean patent application number 10-2025-0047866 filed on Apr. 14, 2025, which is incorporated herein by reference in its entirety.

### BACKGROUND

### 1. Technical Field

Embodiments of the present disclosure relate to a semiconductor device and a partitionability monitoring method thereof.

### 2. Related Art

Due to characteristics such as miniaturization, multifunctionality, and/or low manufacturing cost, semiconductor chips have been spotlighted as important elements in the electronics industry. As the electronics industry has advanced, semiconductor chips have become increasingly highly integrated. As semiconductor chips become highly integrated, the size of each chip is gradually reduced, and the number of semiconductor chips formed on a single wafer increases.

Semiconductor chips are separated into individual semiconductor chips through a cutting process after connecting a ferry wafer and a cell wafer. As semiconductor chips become more highly integrated, the difficulty of visually inspecting the straightness of the cut surfaces of separated semiconductor chips increases.

### SUMMARY

The advantages of the embodiments of the present disclosure are not limited to the advantages mentioned herein, and other advantages not mentioned will be clearly understood by those skilled in the art from the following description.

Embodiments of the present disclosure may provide a semiconductor device and a partitionability monitoring method capable of confirming the straightness of the division when separating a wafer into individual chips.

Embodiments of the present disclosure may provide a semiconductor device comprising a substrate including a chip region and a guard ring region located outside and adjacent to the chip region; a ferry test pad disposed across the guard ring region and a scribe lane region continuously located from the guard ring region; a first cell test pad disposed in the guard ring region and positioned on the ferry test pad; and a scribe lane test pad disposed in the scribe lane region and positioned on the ferry test pad.

Embodiments of the present disclosure may provide a semiconductor device comprising a substrate including a chip region, a guard ring region located outside and adjacent to the chip region, and a scribe lane region positioned adjacent to the guard ring region; a cell test pad disposed across the guard ring region and the scribe lane region; and a ferry test pad disposed in the guard ring region and positioned below the cell test pad.

Embodiments of the present disclosure may provide a partitionability monitoring method of a semiconductor device comprising a cell test pad disposed in the guard ring region; a scribe lane test pad disposed in a scribe lane region continuously located from the guard ring region; and a ferry test pad connected to the cell test pad and the scribe lane test pad, the method comprising applying a voltage to the scribe lane test pad; and measuring a current flowing between the cell test pad and the scribe lane test pad to determine the straightness of the division.

According to embodiments of the present disclosure, it may be possible to provide a semiconductor device and a partitionability monitoring method capable of confirming the straightness of the division when separating a wafer into individual chips.

The advantages of the embodiments of the present disclosure are not limited to those mentioned above, and other advantages not mentioned will be clearly understood by those skilled in the art from the description of the claims.

### BRIEF DESCRIPTION OF THE DRAWINGS

The embodiments of the present disclosure will be more fully understood from the detailed description and accompanying drawings provided below, which are provided solely for description purposes and do not limit the scope of the present disclosure.

FIG. 1 is a view illustrating a planar structure of a semiconductor device according to embodiments of the present disclosure.

FIG. 2 is a view illustrating a cross-sectional structure taken along line A-A' of FIG. 1.

FIG. 3 is a view illustrating another planar structure of a semiconductor device according to embodiments of the present disclosure.

FIG. 4 is a view illustrating a cross-sectional structure taken along line B-B' of FIG. 3.

FIG. 5 is a view illustrating another planar structure of a semiconductor device according to embodiments of the present disclosure.

FIG. 6 is a view illustrating a cross-sectional structure taken along line C-C' of FIG. 5.

FIG. 7 is a view illustrating another cross-sectional structure taken along line C-C' of FIG. 5.

FIG. 8 is a view illustrating another planar structure of a semiconductor device according to embodiments of the present disclosure.

FIG. 9 is a view illustrating a cross-sectional structure taken along line D-D' of FIG. 8.

FIGS. 10 to 16 are views illustrating a method for manufacturing a semiconductor device according to embodiments of the present disclosure.

FIGS. 17 and 18 are views illustrating a cross-sectional structure of a semiconductor device after the partitioning.

FIG. 19 is a view illustrating a partitionability monitoring method of a semiconductor device according to embodiments of the present disclosure.

### DETAILED DESCRIPTION

Hereinafter, embodiments of the present disclosure are described in detail with reference to the accompanying drawings. In assigning reference numerals to components in each drawing, identical components may be assigned the same reference numerals even when shown in different drawings. If details of known art or functions are deemed to obscure the subject matter of this disclosure, such details may be omitted. As used herein, terms such as “includes,” “has,” or “is composed of” in relation to a component may permit the inclusion of additional components unless terms like “only” are explicitly used. Additionally, unless the context clearly indicates otherwise, expressions in the singular, such as “a,” “an,” and “the” are intended to include their plural forms.

Labels such as “first," "second," "A," "B," "(a)," and "(b)" may be used to describe components of this disclosure. These labels are intended merely to distinguish one component from another, and are not intended to limit the nature, order, sequence, or number of the components.

Regarding the description of positional relationships between components, when two or more components are described as being "connected," "coupled," or "linked," it should be understood that they may be directly "connected," "coupled," or "linked," or may have an intervening component. Furthermore, the intervening component may be included in one or more of the two or more components that are “connected,” “coupled,” or “linked” to each other.

When terms such as “after,” “next,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the present disclosure are described in detail with reference to the accompanying drawings.

In the accompanying drawings, regions indicated with reference numerals starting with "1" and regions indicated with reference numerals starting with "2" may each constitute different semiconductor devices. A description for one semiconductor device may be equally applicable to the same configuration of another semiconductor device.

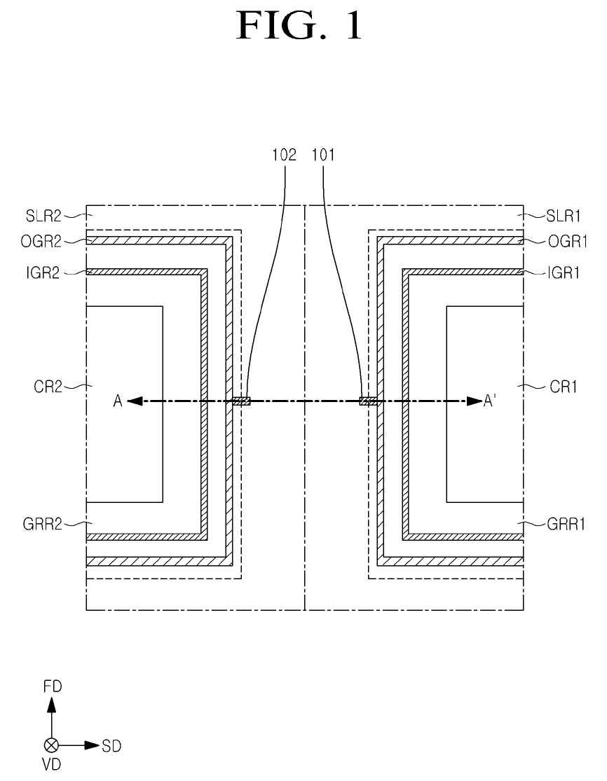

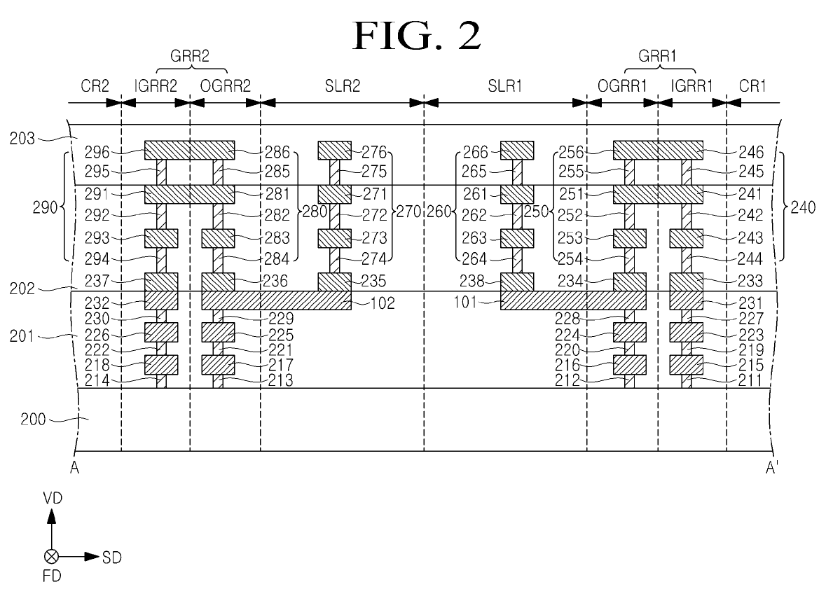

FIG. 1 is a plan view illustrating a structure of a semiconductor device according to embodiments of the present disclosure. FIG. 2 is a cross-sectional view taken along line A-A' of FIG. 1.

Referring to FIGS. 1 and 2, the semiconductor device may include a substrate 200, a first insulating layer 201 over the substrate 200, a second insulating layer 202 over the first insulating layer 201, and a third insulating layer 203 over the second insulating layer 202. The substrate 200, the first insulating layer 201, the second insulating layer 202, and the third insulating layer 203 may be stacked in a third direction VD. The substrate 200, the first insulating layer 201, the second insulating layer 202, and the third insulating layer 203 may each have top and bottom flat surfaces extending parallel to a plane defined by first and second directions FD and SD. The third direction VD may be vertical to a plane defined by the first and second directions FD and SD. The third direction may also be referred to herein as the vertical direction. The semiconductor device may further include a first ferry test pad 101, a first cell test pad 234, a first scribe lane test pad 238, a first internal guard ring wiring structure 240, a first external guard ring wiring structure 250, a first scribe lane wiring structure 260, a first internal ferry lower contact 211, a first internal ferry lower conductive layer 215, a first internal ferry upper contact 219, a first internal ferry upper conductive layer 223, a first ferry guard bonding contact 227, a first ferry guard bonding pad 231, a first external ferry lower contact 212, a first external ferry lower conductive layer 216, a first external ferry upper contact 220, a first external ferry upper conductive layer 224, and a first ferry test contact 228.

The substrate 200 may include a first chip region CR1, a first guard ring region GRR1, and a first scribe lane region SLR1. The first chip region CR1 may be a region where memory cells and peripheral circuits for transmitting various signals and voltages to the memory cells are disposed. The first guard ring region GRR1 may surround the first chip region CR1, and the first scribe lane region SLR1 may surround the first guard ring region GRR1. The first guard ring region GRR1 may include a first internal guard ring region IGRR1 and a first external guard ring region OGRR1. The first internal guard ring region IGRR1 may be a region positioned adjacent to the first chip region CR1 compared to the first external guard ring region OGRR1 which may be positioned adjacent to the to the first scribe lane region SLR1.

The substrate 200 may include a semiconductor substrate such as a silicon wafer or a silicon-on-insulator (SOI) wafer. The substrate 200 may also include a Group III-V compound semiconductor substrate, such as a Gallium arsenide (GaAs) substrate. The substrate 200 may include monocrystalline silicon, polysilicon, amorphous silicon, monocrystalline silicon germanium, polycrystalline silicon germanium, carbon-doped silicon, or a combination thereof. Other semiconductor materials may also be used.

The first, second, and third insulating layers 201, 202, and 203 are disposed in the recited order over the substrate 200 with the first insulating layer 201 disposed on the substrate 200. Although illustrated as single layers, the first, second, and third insulating layers 201, 202, and 203 are not limited thereto and may be multilayer structures. The first, second, and third insulating layers 201, 202, and 203 may each include silicon oxide, silicon nitride, silicon oxynitride, low-k dielectric materials, high-k dielectric materials, or a combination thereof.

The first internal guard ring region IGRR1 may include a first internal guard ring IGR1, and the first external guard ring region OGRR1 may include a first external guard ring OGR1. Similarly, a second internal guard ring region IGRR2 may include a second internal guard ring IGR2, and a second external guard ring region OGRR2 may include a second external guard ring OGR2.

In the first internal guard ring region IGRR1, a first internal ferry lower contact 211, a first internal ferry lower conductive layer 215, a first internal ferry upper contact 219, a first internal ferry upper conductive layer 223, a first ferry guard bonding contact 227, and a first ferry guard bonding pad 231 may be disposed within the first insulating layer 201. The substrate 200, the first internal ferry lower contact 211, the first internal ferry lower conductive layer 215, the first internal ferry upper contact 219, the first internal ferry upper conductive layer 223, the first ferry guard bonding contact 227, and the first ferry guard bonding pad 231 may be sequentially disposed in contact with each other. The first internal ferry lower contact 211, the first internal ferry lower conductive layer 215, the first internal ferry upper contact 219, the first internal ferry upper conductive layer 223, the first ferry guard bonding contact 227, and the first ferry guard bonding pad 231 may include a conductive material such as a metal, a metal oxide, a metal nitride, a metal silicide, polysilicon, conductive carbon, or a combination thereof. A top surface of the first ferry guard bonding pad 231 may be coplanar or substantially coplanar with the interface of the first and second insulating layers 201 and 202.

In the second internal guard ring region IGRR2, a second internal ferry lower contact 214, a second internal ferry lower conductive layer 218, a second internal ferry upper contact 222, a second internal ferry upper conductive layer 226, a second ferry guard bonding contact 230, and a second ferry guard bonding pad 232 may be disposed within the first insulating layer 201. The substrate 200, the second internal ferry lower contact 214, the second internal ferry lower conductive layer 218, the second internal ferry upper contact 222, the second internal ferry upper conductive layer 226, the second ferry guard bonding contact 230, and the second ferry guard bonding pad 232 may be sequentially disposed in contact with each other. The second internal ferry lower contact 214, the second internal ferry lower conductive layer 218, the second internal ferry upper contact 222, the second internal ferry upper conductive layer 226, the second ferry guard bonding contact 230, and the second ferry guard bonding pad 232 may include a conductive material such as a metal, a metal oxide, a metal nitride, a metal silicide, polysilicon, conductive carbon, or a combination thereof. The top surface of the second ferry guard bonding pad 232 may be coplanar or substantially coplanar with the interface between the first and second insulating layers 201 and 202.

The first internal ferry lower contact 211, the first internal ferry lower conductive layer 215, the first internal ferry upper contact 219, the first internal ferry upper conductive layer 223, the first ferry guard bonding contact 227, and the first ferry guard bonding pad 231 may be continuously disposed along a boundary between the first chip region CR1 and the first guard ring region GRR1.

In the first external guard ring region OGRR1, a first external ferry lower contact 212, a first external ferry lower conductive layer 216, a first external ferry upper contact 220, a first external ferry upper conductive layer 224, a first ferry test contact 228, and a first ferry test pad 101 may be disposed within the first insulating layer 201. The substrate 200, the first external ferry lower contact 212, the first external ferry lower conductive layer 216, the first external ferry upper contact 220, the first external ferry upper conductive layer 224, the first ferry test contact 228, and the first ferry test pad 101 may be sequentially contacted and disposed within the first insulating layer 201. A top surface of the first ferry test pad 101 may form substantially the same plane as a top surface of the first ferry guard bonding pad 231. The first external ferry lower contact 212, the first external ferry lower conductive layer 216, the first external ferry upper contact 220, the first external ferry upper conductive layer 224, the first ferry test contact 228, and the first ferry test pad 101 may include a conductive material such as, for example, metal, metal oxide, metal nitride, metal silicide, polysilicon, conductive carbon, or a combination thereof.

In the second external guard ring region OGRR2, a second external ferry lower contact 213, a second external ferry lower conductive layer 217, a second external ferry upper contact 221, a second external ferry upper conductive layer 225, a second ferry test contact 229, and a second ferry test pad 102 may be disposed within the first insulating layer 201. The substrate 200, the second external ferry lower contact 213, the second external ferry lower conductive layer 217, the second external ferry upper contact 221, the second external ferry upper conductive layer 225, the second ferry test contact 229, and the second ferry test pad 102 may be sequentially contacted and disposed within the first insulating layer 201. A top surface of the second ferry test pad 102 may form substantially the same plane as a top surface of the second ferry guard bonding pad 232. The second external ferry lower contact 213, the second external ferry lower conductive layer 217, the second external ferry upper contact 221, the second external ferry upper conductive layer 225, the second ferry test contact 229, and the second ferry test pad 102 may include a conductive material such as, for example, metal, metal oxide, metal nitride, metal silicide, polysilicon, conductive carbon, or a combination thereof.

A bottom surface of the first cell test pad 234 may contact a top surface of the first ferry test pad 101. A width in a second direction SD of the first cell test pad 234 may be thinner than a width in the second direction SD of the first ferry test pad 101.

The first external ferry lower contact 212, the first external ferry lower conductive layer 216, the first external ferry upper contact 220, the first external ferry upper conductive layer 224, the first ferry test contact 228, and the first ferry test pad 101 may be continuously disposed along a boundary between the first chip region CR1 and the first guard ring region GRR1.

In the first guard ring region GRR1, a first cell guard bonding pad 233, a first internal guard ring wiring structure 240, a first cell test pad 234, and a first external guard ring wiring structure 250 may be disposed within the second insulating layer 202 and the third insulating layer 203. The first internal guard ring wiring structure 240 may contact a top surface of the first cell guard bonding pad 233. The first external guard ring wiring structure 250 may contact a top surface of the first cell test pad 234. The first cell guard bonding pad 233, the first cell test pad 234, the first external guard ring wiring structure 250, and the first internal guard ring wiring structure 240 may include a conductive material such as, for example, metal, metal oxide, metal nitride, metal silicide, polysilicon, conductive carbon, or a combination thereof.

The first internal guard ring wiring structure 240 may include a first internal cell lower contact 244, a first internal cell lower conductive layer 243, a first internal cell intermediate contact 242, a first internal cell intermediate conductive layer 241, a first internal cell upper contact 245, and a first internal cell upper conductive layer 246. The first external guard ring wiring structure 250 may include a first external cell lower contact 254, a first external cell lower conductive layer 253, a first external cell intermediate contact 252, a first external cell intermediate conductive layer 251, a first external cell upper contact 255, and a first external cell upper conductive layer 256.

In the second guard ring region GRR2, a second cell guard bonding pad 237, a second internal guard ring wiring structure 290, a second cell test pad 236, and a second external guard ring wiring structure 280 may be disposed within the second insulating layer 202 and the third insulating layer 203. The second internal guard ring wiring structure 290 may contact a top surface of the second cell guard bonding pad 237. The second external guard ring wiring structure 280 may contact a top surface of the second cell test pad 236. The second cell guard bonding pad 237, the second cell test pad 236, the second external guard ring wiring structure 280, and the second internal guard ring wiring structure 290 may include a conductive material such as, for example, metal, metal oxide, metal nitride, metal silicide, polysilicon, conductive carbon, or a combination thereof.

The second internal guard ring wiring structure 290 may include a second internal cell lower contact 294, a second internal cell lower conductive layer 293, a second internal cell intermediate contact 292, a second internal cell intermediate conductive layer 291, a second internal cell upper contact 295, and a second internal cell upper conductive layer 296. The second external guard ring wiring structure 280 may include a second external cell lower contact 284, a second external cell lower conductive layer 283, a second external cell intermediate contact 282, a second external cell intermediate conductive layer 281, a second external cell upper contact 285, and a second external cell upper conductive layer 286.

The first internal guard ring IGR1 and the first external guard ring OGR1 may be connected through the internal guard ring wiring structure 240 and the external guard ring wiring structure 250.

The first cell guard bonding pad 233, the first internal guard ring wiring structure 240, the first cell test pad 234, and the first external guard ring wiring structure 250 may be continuously disposed along a boundary between the first chip region CR1 and the first guard ring region GRR1.

According to embodiments of the present disclosure, the first internal guard ring IGR1 and the first external guard ring OGR1 may be continuously disposed in a linear form surrounding the first chip region CR1, thereby protecting the semiconductor from moisture penetration and the like.

The first internal cell lower conductive layer 243 and the first external cell lower contact 254 may be in contact. The first internal cell intermediate conductive layer 241 and the first external cell intermediate conductive layer 251 may be in contact. The first internal cell upper conductive layer 246 and the first external cell upper conductive layer 256 may be in contact.

In the first scribe lane region SLR1, a first ferry test pad 101, a first scribe lane test pad 238, and a first scribe lane wiring structure 260 may be disposed. The first scribe lane wiring structure 260 may include a first scribe lane lower contact 264, a first scribe lane lower conductive layer 263, a first scribe lane intermediate contact 262, a first scribe lane intermediate conductive layer 261, a first scribe lane upper contact 265, and a first scribe lane upper conductive layer 266. The first ferry test pad 101, the first scribe lane test pad 238, and the first scribe lane wiring structure 260 may include a conductive material such as, for example, metal, metal oxide, metal nitride, metal silicide, polysilicon, conductive carbon, or a combination thereof.

In the second scribe lane region SLR2, a second ferry test pad 102, a second scribe lane test pad 235, and a second scribe lane wiring structure 270 may be disposed. The second scribe lane wiring structure 270 may include a second scribe lane lower contact 274, a second scribe lane lower conductive layer 273, a second scribe lane intermediate contact 272, a second scribe lane intermediate conductive layer 271, a second scribe lane upper contact 275, and a second scribe lane upper conductive layer 276.

The second scribe lane wiring structure 270 may be positioned over the second scribe lane test pad 235. The second ferry test pad 102, the second scribe lane test pad 235, and the second scribe lane wiring structure 270 may include a conductive material such as, for example, metal, metal oxide, metal nitride, metal silicide, polysilicon, conductive carbon, or a combination thereof.

A bottom surface of the first scribe lane test pad 238 may contact a top surface of the first ferry test pad 101. A width in the second direction SD of the first scribe lane test pad may be thinner than a width in the second direction SD of the first ferry test pad 101. The first scribe lane test pad 238 may be disposed spaced apart from the first cell test pad 234.

The first scribe lane wiring structure 260 may have a structure physically separated from the first external guard ring wiring structure 250. The first scribe lane wiring structure 260 may be electrically connected to the first external guard ring wiring structure 250 through the first ferry test pad 101.

A sum of widths in the second direction SD of the first scribe lane region SLR1 and the second scribe lane region SLR2 may be 40 μm or more and 60 μm or less.

A top surface of the first internal cell upper conductive layer 246, a top surface of the first external cell upper conductive layer 256, and a top surface of the first scribe lane upper conductive layer 266 may form the same or substantially the same plane.

The first ferry test pad 101 may be disposed across the first external guard ring region OGRR1 and the first scribe lane region SLR1.

The first ferry test pad 101, the first scribe lane test pad 238, and the first scribe lane wiring structure 260 may be continuously disposed along a boundary between the first chip region CR1 and the first guard ring region GRR1.

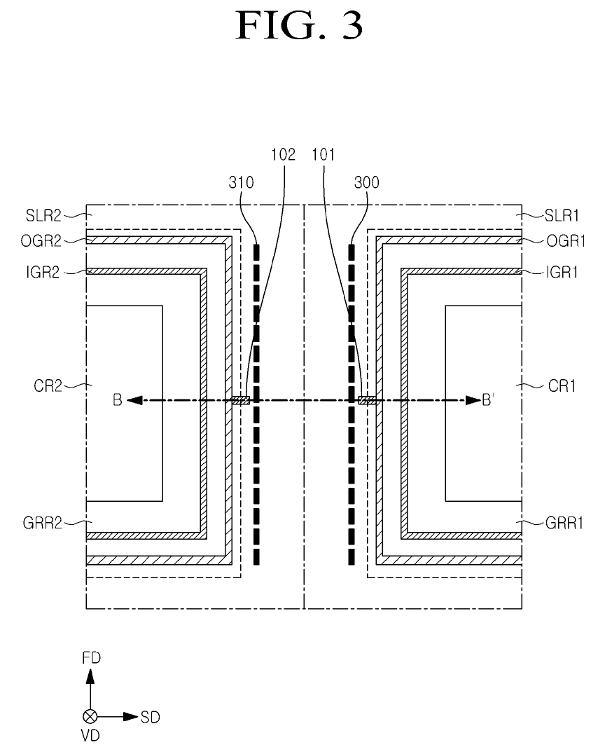

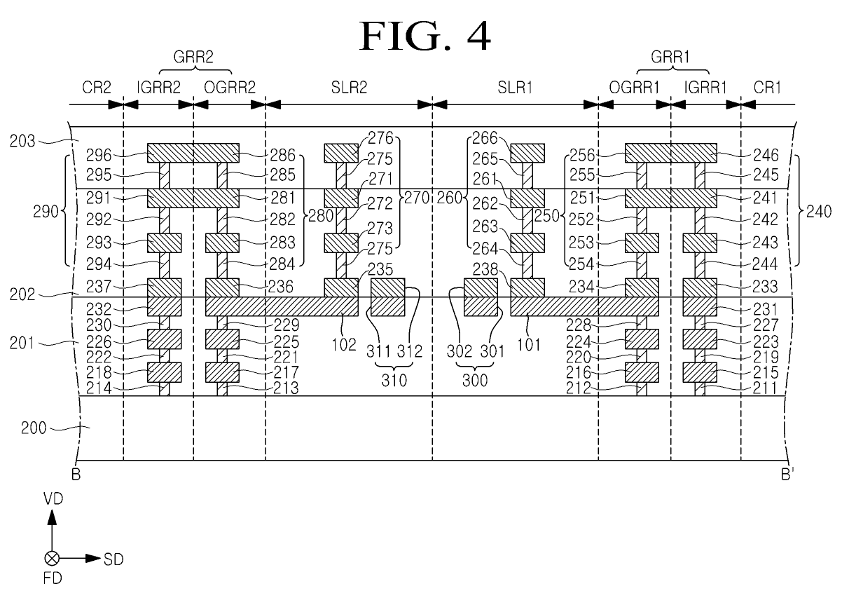

FIG. 3 illustrates another planar structure of a semiconductor device according to embodiments of the present disclosure. FIG. 4 illustrates a cross-sectional view of the B-B' portion of FIG. 3.

Referring to FIGS. 3 and 4, a first dummy pad 300 may be disposed within the first insulating layer 201 and the second insulating layer 202 in the first scribe lane region SLR1. The first dummy pad 300 may include a first ferry dummy pad 301 and a first cell dummy pad 302 disposed in the first and second insulating layers respectively. The first ferry dummy pad 301 and the first cell dummy pad 302 may contact each other at an interface that is coplanar or substantially coplanar with the interface between the first and second insulating layers 201 and 202. The first ferry dummy pad 301 and the first cell dummy pad 302 may include a conductive material such as, for example, metal, metal oxide, metal nitride, metal silicide, polysilicon, conductive carbon, or a combination thereof.

In the second scribe lane region SLR2, a second dummy pad 310 may be disposed within the first insulating layer 201 and the second insulating layer 202. The second dummy pad 310 may include a second ferry dummy pad 311 and a second cell dummy pad 312. The second ferry dummy pad 311 and the second cell dummy pad 312 may contact each other at an interface which is coplanar or substantially coplanar with the interface between the first and second insulating layers 201 and 202. The second ferry dummy pad 311 and the second cell dummy pad 312 may include a conductive material such as, for example, metal, metal oxide, metal nitride, metal silicide, polysilicon, conductive carbon, or a combination thereof.

The first cell dummy pad 302 may be disposed spaced apart from the first scribe lane test pad 238. The first ferry dummy pad 301 may be disposed spaced apart from the first ferry test pad 101.

A top surface of the first ferry dummy pad 301 may form substantially the same plane as a top surface of the first ferry test pad 101. A bottom surface of the first cell dummy pad 302 may form the same or substantially the same plane as a bottom surface of the first cell test pad 234.

A top surface of the first ferry dummy pad 301 and a bottom surface of the first cell dummy pad 302 may be in contact. A width in the second direction SD of the first ferry dummy pad 301 may be the same as a width in the second direction SD of the first cell dummy pad 302.

The first ferry dummy pad 301 and the first cell dummy pad 302 may be discontinuously disposed along a boundary between the first chip region CR1 and the first guard ring region GRR1. Referring to FIG. 3, the first ferry dummy pad 301 and the first cell dummy pad 302 (collectively referred to as 300) may be discontinuously disposed parallel to one side or the entire side of the boundary between the first chip region CR1 and the first guard ring region GRR1. The second dummy pad 310 (311, 312) may be discontinuously disposed parallel to one side or the entire side of the boundary between the second chip region CR2 and the second guard ring region GRR2.

The first ferry dummy pad 301 may be disposed farther from the first chip region CR1 than the first ferry test pad 101. The first cell dummy pad 302 may be disposed farther from the first guard ring region GRR1 than the first scribe lane test pad 238. The first ferry dummy pad 301 and the first cell dummy pad 302 may be fully overlapping with each other in the third direction VD. In this configuration, 'fully overlapping' indicates that the first ferry dummy pad 301 and the first cell dummy pad 302 are aligned such that their entire surface areas coincide with each other along the third direction (VD), without any portion of one extending beyond the boundaries of the other.

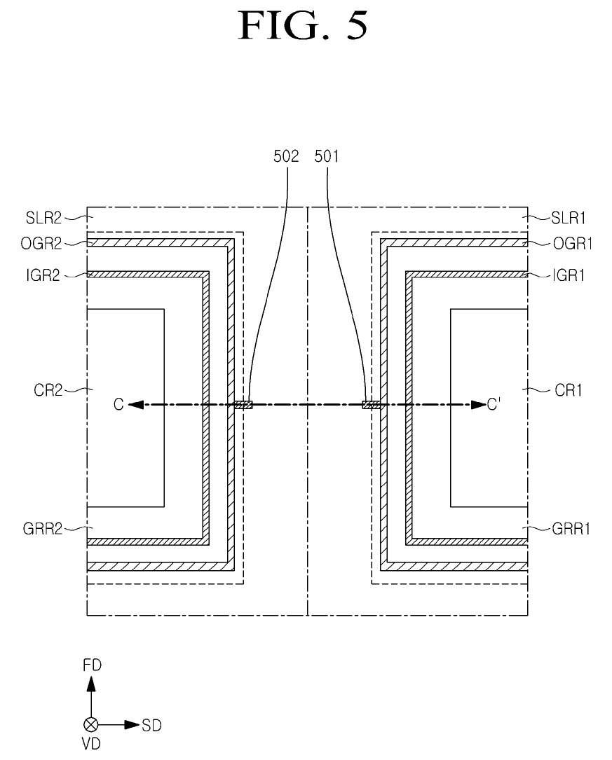

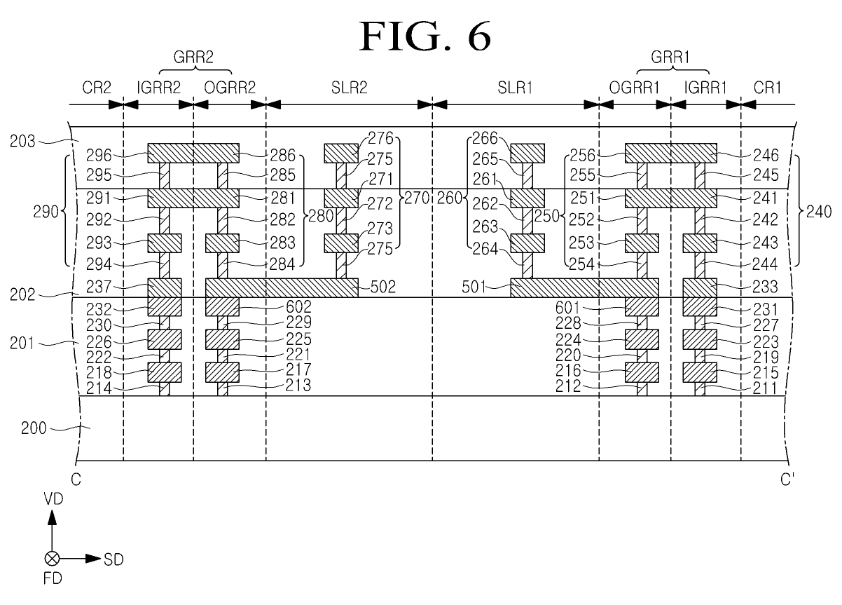

FIG. 5 illustrates another planar structure of a semiconductor device according to embodiments of the present disclosure. FIG. 6 illustrates a cross-sectional view of the C-C' portion of FIG. 5.

Referring to FIGS. 5 and 6, a first cell test pad 501 may be disposed within the second insulating layer 202. The first cell test pad 501 may be disposed across the first external guard ring region OGRR1 and the first scribe lane region SLR1. The first cell test pad 501 may extend partially inside the first external ring region OGRR1 and also inside the first scribe lane region SLR1 along the second direction SD.

A second cell test pad 502 may be disposed within the second insulating layer 202. The second cell test pad 502 may be disposed across the second external guard ring region OGRR2 and the second scribe lane region SLR2. The second cell test pad 502 may extend partially inside the second external ring region OGRR2 and also inside the second scribe lane region SLR2 along the second direction SD.

In the first external guard ring region OGRR1, a first ferry test pad 601 may be disposed within the first insulating layer 201. A top surface of the first ferry test pad 601 may contact a bottom surface of the first cell test pad 501. The top surface of the first ferry test pad 601 may contact the bottom surface of the first cell test pad 501 at a level coplanar or substantially coplanar with the interface between the first and second insulating layers 201 and 202. A width in the second direction SD of the first ferry test pad 601 may be thinner than a width in the second direction SD of the first cell test pad 501. As illustrated in FIG. 6, an edge of the first ferry test pad 601 which is disposed within the first external guard ring region OGRR1 may be aligned in the third direction VD with an edge of the first cell test pad 501.

In the second external guard ring region OGRR2, a second ferry test pad 602 may be disposed within the first insulating layer 201. A top surface of the second ferry test pad 602 may contact a bottom surface of the second cell test pad 502. A width in the second direction SD of the second ferry test pad 602 may be thinner than a width in the second direction SD of the second cell test pad 502. The top surface of the second ferry test pad 602 may contact the bottom surface of the second cell test pad 501 at a level coplanar or substantially coplanar with the interface between the first and second insulating layers 201 and 202. A width in the second direction SD of the second ferry test pad 602 may be thinner than a width in the second direction SD of the second cell test pad 502. As illustrated in FIG. 6, an edge of the second ferry test pad 602 which is disposed within the second external guard ring region OGRR2 may be aligned in the third direction VD with an edge of the second cell test pad 502.

As another example,(not shown), the first ferry test pad 601 may be disposed across the first external guard ring region OGRR1 and the first scribe lane region SLR1. Also, in another example (not shown), the second ferry test pad 602 may be disposed across the second external guard ring region OGRR2 and the second scribe lane region SLR2.

The first ferry test pad 601 and the first cell test pad 501 may include a conductive material such as, for example, metal, metal oxide, metal nitride, metal silicide, polysilicon, conductive carbon, or a combination thereof.

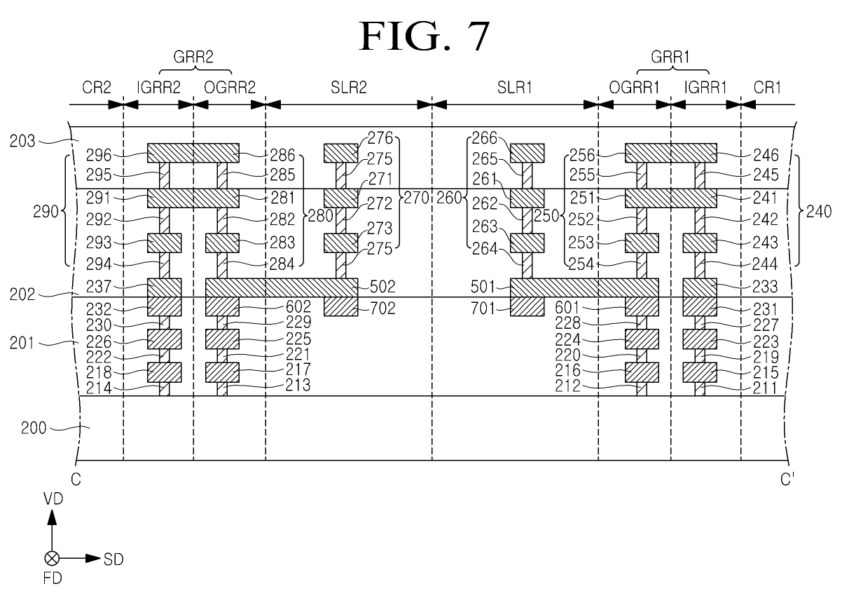

FIG. 7 illustrates another cross-section of the C-C' portion of FIG. 5 according to embodiments of the present disclosure.

Referring to FIGS. 5 and 7, a first scribe lane test pad 701 may be disposed within the first insulating layer 201 in the first scribe lane region SLR1.

In the second scribe lane region SLR2, a second scribe lane test pad 702 may be disposed within the first insulating layer 201.

A top surface of the first scribe lane test pad 701 may contact a bottom surface of the first cell test pad 501. A width in the second direction SD of the first scribe lane test pad 701 may be thinner than a width in the second direction SD of the first cell test pad 501. A top surface of the first scribe lane test pad 701 may form substantially the same plane as a top surface of the first ferry test pad 601. The first scribe lane test pad 701 may have a structure physically separated from the first ferry test pad 601.

The first scribe lane test pad 701 may include a conductive material such as, for example, metal, metal oxide, metal nitride, metal silicide, polysilicon, conductive carbon, or a combination thereof.

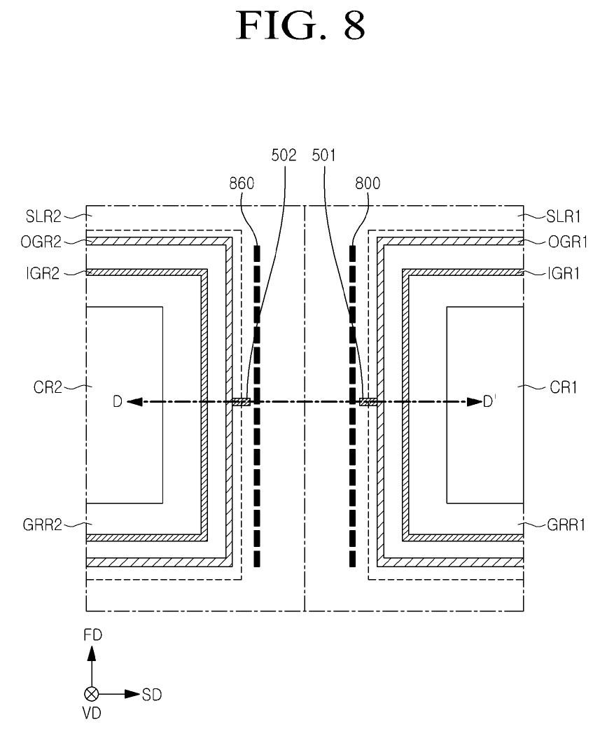

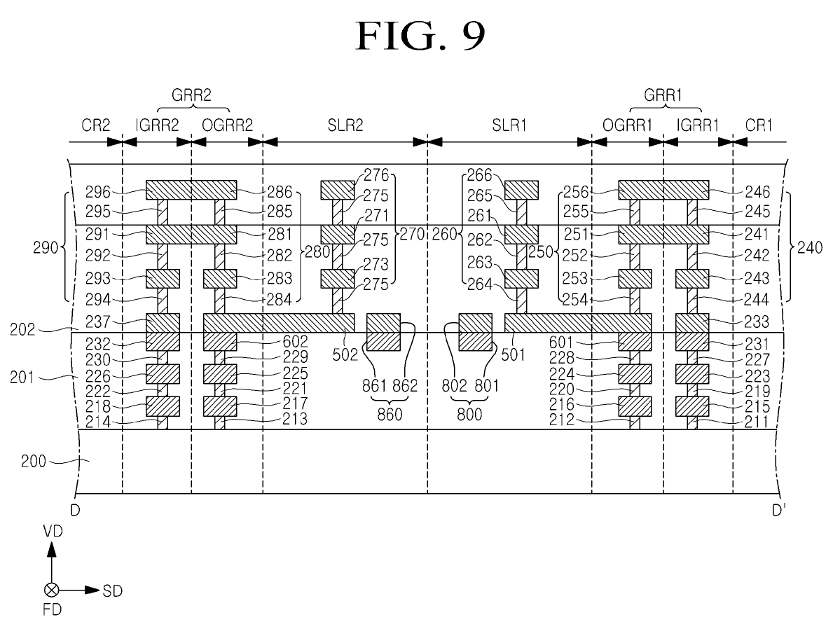

FIG. 8 illustrates another planar structure of a semiconductor device according to embodiments of the present disclosure. FIG. 9 illustrates a cross-sectional view of the D-D' portion of FIG. 8.

Referring to FIGS. 8 and 9, a first dummy pad 800 may be disposed in the first scribe lane region SLR1. The first dummy pad 800 may include a first ferry dummy pad 801 and a first cell dummy pad 802. The first ferry dummy pad 801 and the first cell dummy pad 802 may include a conductive material such as, for example, metal, metal oxide, metal nitride, metal silicide, polysilicon, conductive carbon, or a combination thereof. The first ferry dummy pad 801 and the first cell dummy pad 802 may be fully overlapping with each other in the third direction VD.

In the second scribe lane region SLR2, a second dummy pad 860 may be disposed. The second dummy pad 860 may include a second ferry dummy pad 861 and a second cell dummy pad 862. The second ferry dummy pad 861 and the second cell dummy pad 862 may include a conductive material such as, for example, metal, metal oxide, metal nitride, metal silicide, polysilicon, conductive carbon, or a combination thereof. The second ferry dummy pad 861 and the second cell dummy pad 862 may be fully overlapping with each other in the third direction VD.

The first cell dummy pad 802 may be disposed spaced apart from the first cell test pad 501. The first ferry dummy pad 801 may be disposed spaced apart from the first ferry test pad 601.

A top surface of the first ferry dummy pad 801 may form substantially the same plane as a top surface of the first ferry test pad 601. A bottom surface of the first cell dummy pad 802 may form substantially the same plane as a bottom surface of the cell test pad 501.

A top surface of the first ferry dummy pad 801 and a bottom surface of the first cell dummy pad 802 may be in contact. A width in the second direction SD of the first ferry dummy pad 801 and a width in the second direction SD of the first cell dummy pad 802 may be the same.

Referring to FIG. 8, the first ferry dummy pad 801 and the first cell dummy pad 802 (collectively referred to as the first dummy pad 800) may be discontinuously disposed along a boundary between the first chip region CR1 and the first guard ring region GRR1. The first ferry dummy pad 801 and the first cell dummy pad 802 may be discontinuously disposed on one side or the entire side of the boundary between the first chip region CR1 and the first guard ring region GRR1.

The first cell dummy pad 802 may be disposed farther from the first chip region CR1 than the cell test pad 501. The first ferry dummy pad 801 may be disposed farther from the first guard ring region GRR1 than the first scribe lane test pad 238.

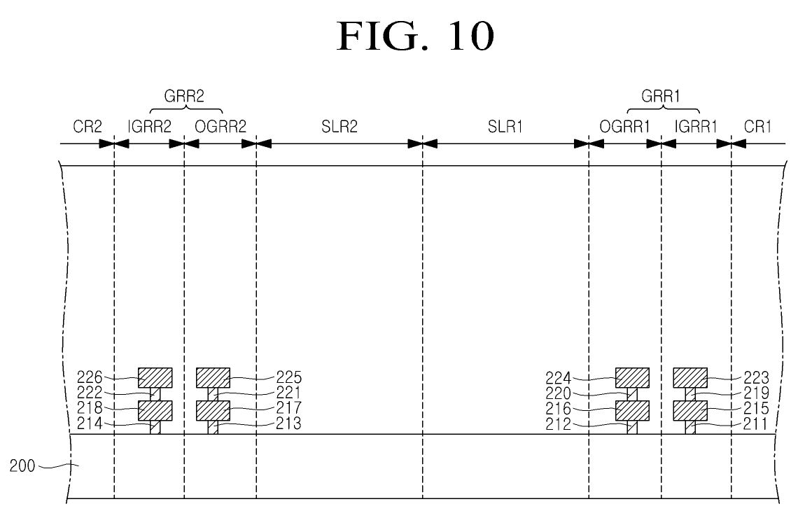

FIGS. 10 to 16 illustrate a manufacturing method of a semiconductor device according to embodiments of the present disclosure.

Referring to FIG. 10, a first internal ferry lower contact 211 and a first external ferry lower contact 212 are formed on the substrate 200. A first internal ferry lower conductive layer 215 is formed on the first internal ferry lower contact 211, and a first external ferry lower conductive layer 216 is formed on the first external ferry lower contact 212. A first internal ferry upper contact 219 is formed on the first internal ferry lower conductive layer 215, and a first external ferry upper contact 220 is formed on the first external ferry lower conductive layer 216. A first internal ferry upper conductive layer 223 is formed on the first internal ferry upper contact 219, and a first external ferry upper conductive layer 224 is formed on the first external ferry upper contact 220.

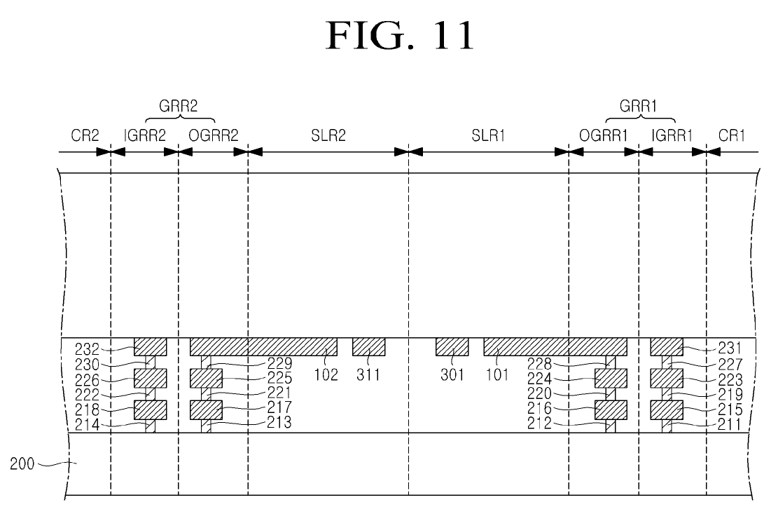

Referring to FIG. 11, a first ferry guard bonding contact 227 may be formed on the first internal ferry upper conductive layer 223, and a first ferry test contact 228 may be formed on the first external ferry upper conductive layer 224. A first ferry guard bonding pad 231 may be formed on the first ferry guard bonding contact 227, and a first ferry test pad 101 may be formed on the first ferry test contact 228. The first ferry test pad 101 may be formed across the first guard ring region GRR1 and the first scribe lane region SLR1. In an embodiment, a first ferry dummy pad 301 may be formed in the first scribe lane region SLR1.

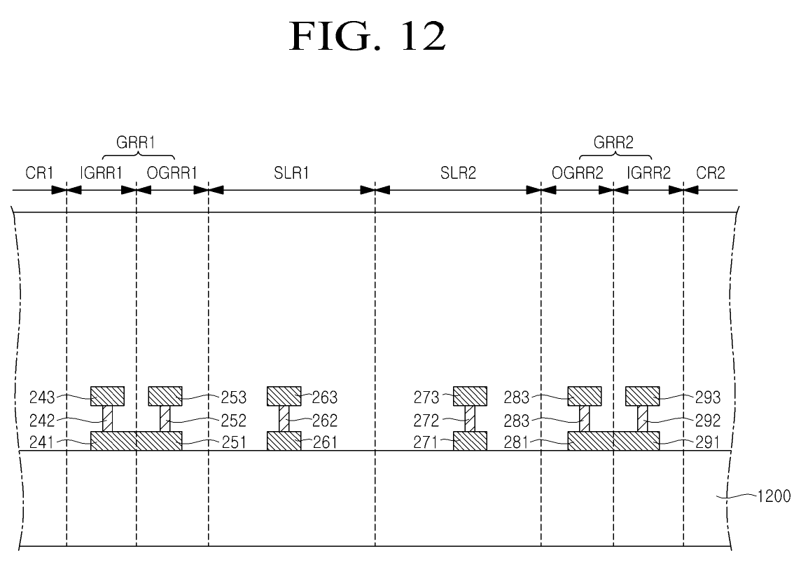

Referring to FIG. 12, a first internal cell intermediate conductive layer 241, a first external cell intermediate conductive layer 251, and a first scribe lane intermediate conductive layer 261 may be formed on a cell wafer substrate 1200. A first internal cell intermediate contact 242 may be formed on the first internal cell intermediate conductive layer 241, a first external cell intermediate contact 252 may be formed on the first external cell intermediate conductive layer 251, and a first scribe lane intermediate contact 262 may be formed on the first scribe lane intermediate conductive layer 261. A first internal cell lower conductive layer 243 may be formed on the first internal cell intermediate contact 242, a first external cell lower contact 254 may be formed on the first external cell intermediate contact 252, and a first scribe lane lower conductive layer 263 may be formed on the first scribe lane intermediate contact 262.

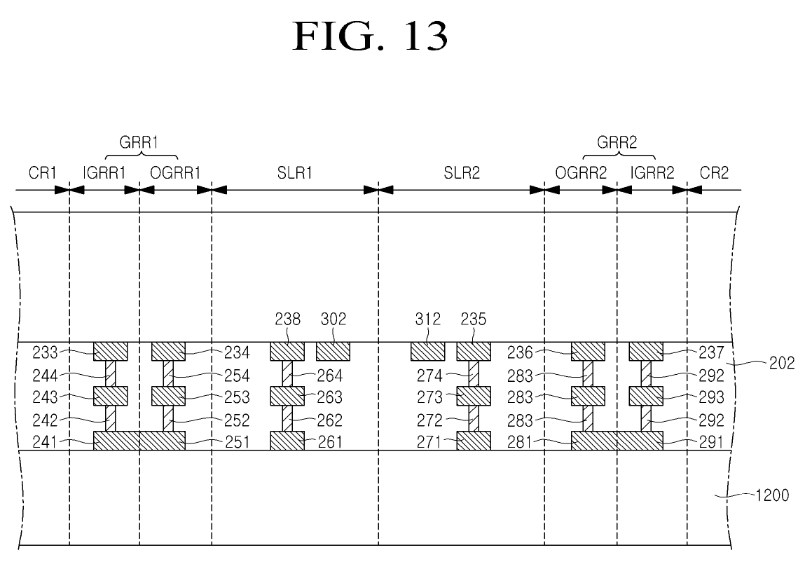

Referring to FIG. 13, a first internal cell lower contact 244 may be formed on the first internal cell lower conductive layer 243, a first external cell lower contact 254 may be formed on the first external cell lower conductive layer 253, and a first scribe lane lower contact 264 may be formed on the first scribe lane lower conductive layer 263. A first cell guard bonding pad 233 may be formed on the first internal cell lower contact 244, a first cell test pad 234 may be formed on the first external cell lower contact 254, and a scribe lane test pad may be formed on the first scribe lane lower contact 264. In an embodiment, a first cell dummy pad 302 may be formed in the first scribe lane region SLR1.

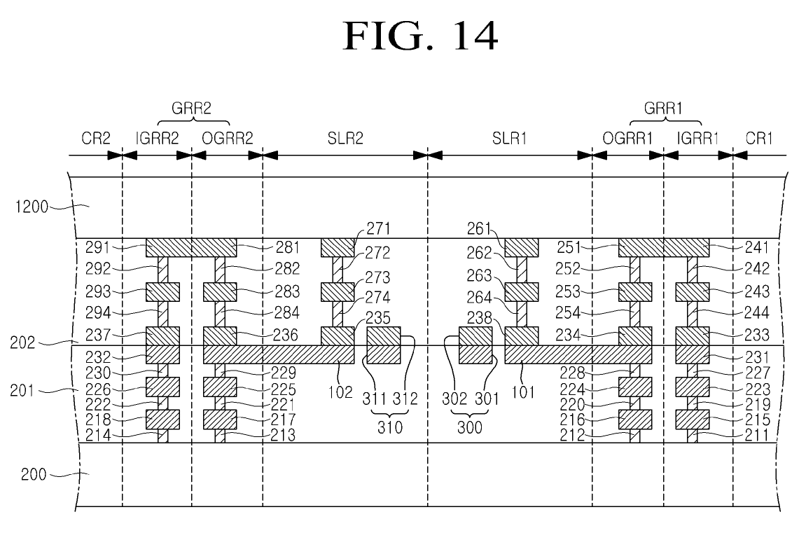

Referring to FIG. 14, the semiconductor device of FIG. 11 and the semiconductor device of FIG. 13 may be bonded together. The semiconductor device of FIG. 13 may be bonded in a flipped state. In this case, the first cell guard bonding pad 233 may contact the first ferry guard bonding pad 231. The first cell test pad 234 and the scribe lane test pad may contact the first ferry test pad 101. In an embodiment, the first cell dummy pad 302 and the first ferry dummy pad 301 may contact each other.

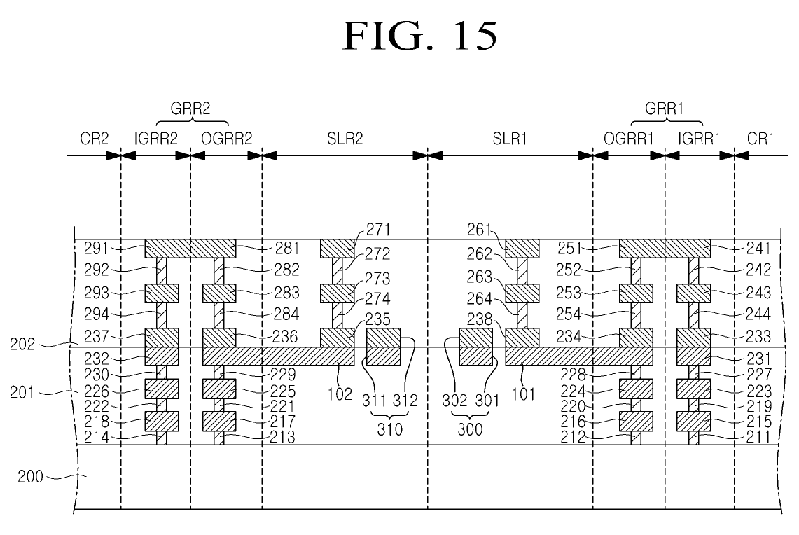

Referring to FIG. 15, the cell wafer substrate 1200 may be removed. The process of removing the cell wafer substrate 1200 may include, for example, a wet etching process.

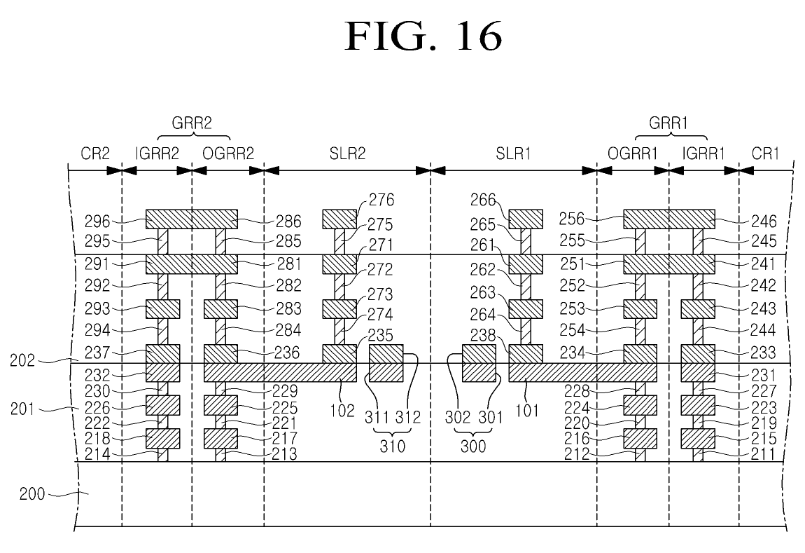

Referring to FIG. 16, a first internal cell upper contact 245 may be formed on the first internal cell intermediate conductive layer 241, a first external cell upper contact 255 may be formed on the first external cell intermediate conductive layer 251, and a first scribe lane upper contact 265 may be formed on the first scribe lane intermediate conductive layer 261. A first internal cell upper conductive layer 246 may be formed on the first internal cell upper contact 245, a first external cell upper conductive layer 256 may be formed on the first external cell upper contact 255, and a first scribe lane upper conductive layer 266 may be formed on the first scribe lane upper contact 265.

According to embodiments of the present disclosure, since the first ferry test pad 101 or the first cell test pad 501 is disposed across the first external guard ring region OGRR1 and the first scribe lane region SLR1, it may be possible to electrically determine whether the straightness of the cut surface of the divided semiconductor chips is acceptable.

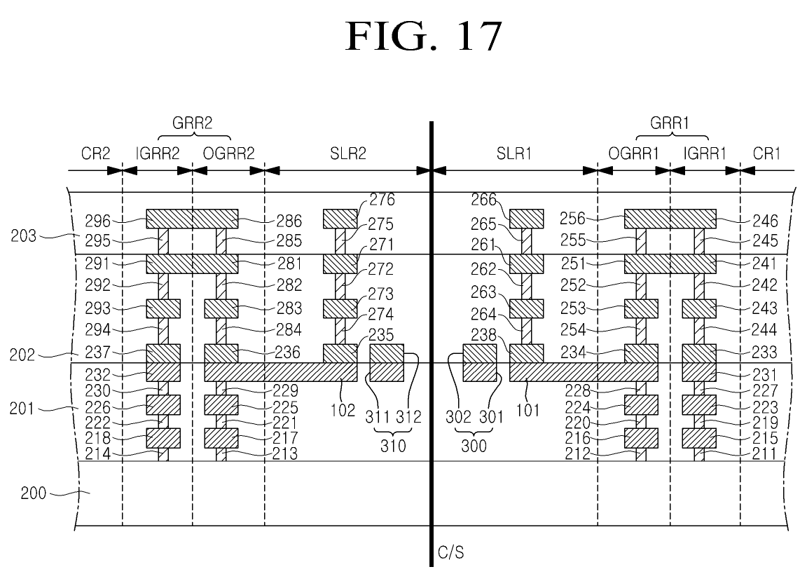

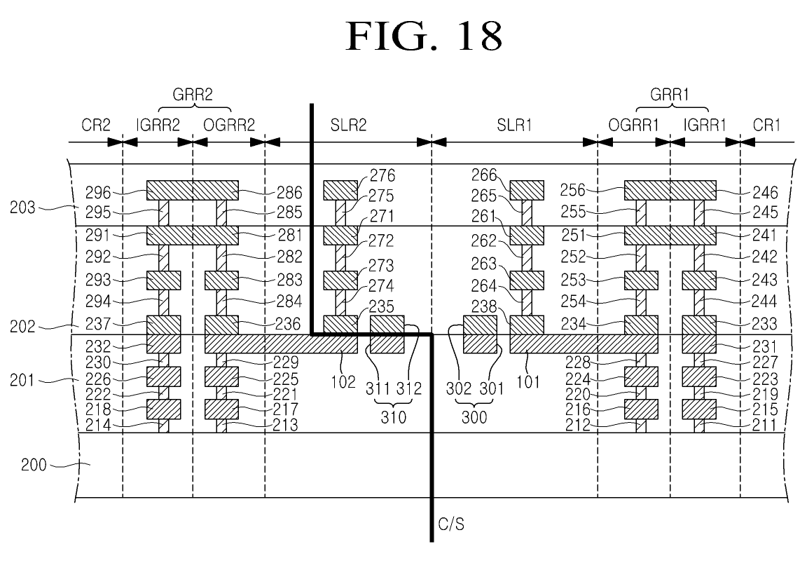

FIGS. 17 and 18 are diagrams including the cut surface structure of a semiconductor device according to embodiments of the present disclosure.

Referring to FIG. 17, the semiconductor device may be divided along a boundary surface between the first scribe lane region SLR1 of one semiconductor device and the second scribe lane region SLR2 of an adjacent semiconductor device.

As an example, a ground voltage may be applied to the first cell test pad 234, and an arbitrary voltage may be applied to the first scribe lane test pad 238. In this case, if the division is made as shown in FIG. 17, it may be confirmed that a current flows between the first cell test pad 234 and the first scribe lane test pad 238, indicating that the straightness of the division is acceptable.

Referring to FIG. 18, the semiconductor device may be divided along a portion of the boundary surface between the first scribe lane region SLR1 of one semiconductor device and the second scribe lane region SLR2 of an adjacent semiconductor device, including a portion of the interface between the first insulating layer 201 and the second insulating layer 202. As an example, delamination may occur at the interface between the first ferry test pad 101 and the first scribe lane test pad 238.

As an example, a ground voltage may be applied to the first cell test pad 234, and an arbitrary voltage may be applied to the first scribe lane test pad 238. In this case, if division occurs as shown in FIG. 18, no current will flow between the first cell test pad 234 and the first scribe lane test pad 238, indicating that the division lacks straightness.

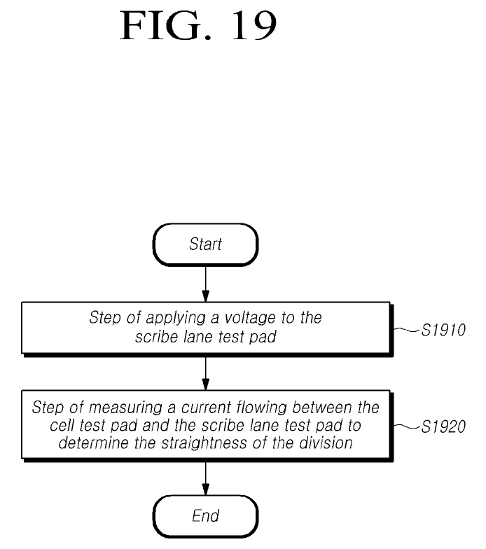

FIG. 19 illustrates a partitionability monitoring method of a semiconductor device according to embodiments of the present disclosure. Hereinafter, the method will be described by taking the semiconductor device described with reference to FIG. 2 as an example.

First, the voltage is applied to the first scribe lane test pad 238 within the semiconductor device (S1910). The first external cell upper conductive layer 256 may be grounded, and an arbitrary voltage may be applied to the first scribe lane upper conductive layer 266 by contacting a probe.

Then, the current flowing between the first cell test pad 234 and the first scribe lane test pad 238 is measured to determine the straightness of the division (S1920). The presence or absence of current flow may be checked by contacting probes respectively to the first external cell upper conductive layer 256 and the first scribe lane upper conductive layer 266.

If division occurs as shown in FIG. 17, current will flow between the first cell test pad 234 and the first scribe lane test pad 238, indicating that the straightness of the division is acceptable. If division occurs as shown in FIG. 18, no current will flow between the first cell test pad 234 and the first scribe lane test pad 238, indicating that the division lacks straightness.

Conventionally, the straightness of the division of semiconductor chips was visually inspected. However, according to embodiments of the present disclosure, the straightness of the division is determined by measuring the current flowing between the first cell test pad 234 and the first scribe lane test pad 238, thereby allowing for effective determination of division straightness or division defects.

The above description provides illustrative embodiments of the present disclosure. Accordingly, a person of ordinary skill in the art to which the present disclosure pertains may make various modifications and variations to the embodiments without departing from the essential characteristics of the present disclosure. In addition, the embodiments disclosed in the present disclosure are not intended to limit the scope of the present disclosure but rather to describe it. Therefore, the scope of the present disclosure should not be limited by the embodiments and many variations thereof and additional embodiments may be readily envisioned by those with ordinary skill in the art. Furthermore, the embodiments may be combined to form additional embodiments.

What is claimed is:

1. A semiconductor device comprising:
a substrate including a chip region and a guard ring region located outside and adjacent to the chip region;
a ferry test pad disposed across the guard ring region and a scribe lane region continuously located from the guard ring region;
a cell test pad disposed in the guard ring region and positioned on the ferry test pad; and
a scribe lane test pad disposed in the scribe lane region and positioned on the ferry test pad.

2. The semiconductor device according to claim 1, wherein a width of the scribe lane test pad is thinner than a width of the ferry test pad.

3. The semiconductor device according to claim 1, wherein the cell test pad is spaced apart from the scribe lane test pad.

4. The semiconductor device according to claim 1, wherein a bottom surface of the cell test pad and a bottom surface of the scribe lane test pad contact a top surface of the ferry test pad.

5. The semiconductor device according to claim 1, wherein the cell test pad is disposed along a boundary between the chip region and the guard ring region.

6. The semiconductor device according to claim 1, further comprising:
an external guard ring wiring structure disposed on the cell test pad; and
a scribe lane wiring structure disposed on the scribe lane test pad,
wherein the scribe lane wiring structure and the external guard ring wiring structure are physically separated.

7. The semiconductor device according to claim 6,
wherein the external guard ring wiring structure and the scribe lane wiring structure comprise conductive layers, and
wherein a first conductive layer among the conductive layers of the external guard ring wiring structure farthest from the cell test pad is positioned on the same layer as a second conductive layer among the conductive layers of the scribe lane wiring structure farthest from the scribe lane test pad.

8. The semiconductor device according to claim 6, wherein the external guard ring wiring structure and the scribe lane wiring structure are electrically connected through the ferry test pad.

9. The semiconductor device according to claim 6, further comprising:
an internal guard ring disposed in the guard ring region; and
an external guard ring disposed in the guard ring region and farther from the chip region than the internal guard ring,
wherein the external guard ring comprises at least a portion of the ferry test pad, the cell test pad, and the external guard ring wiring structure.

10. The semiconductor device according to claim 9, wherein the internal guard ring comprises:
a ferry guard bonding pad disposed in the guard ring region, adjacent to the chip region, and positioned on the same layer as the ferry test pad;
a cell guard bonding pad disposed on the ferry guard bonding pad; and
an internal guard ring wiring structure disposed on the cell guard bonding pad.

11. The semiconductor device according to claim 10, wherein the internal guard ring and the external guard ring are connected through the external guard ring wiring structure and the internal guard ring wiring structure.

12. The semiconductor device according to claim 1, further comprising:
a ferry dummy pad disposed in the scribe lane region and spaced apart from the ferry test pad; and
a cell dummy pad disposed on the ferry dummy pad.

13. The semiconductor device according to claim 12, wherein a top surface of the ferry dummy pad and a top surface of the ferry test pad are on the same plane.

14. The semiconductor device according to claim 12, wherein the ferry dummy pad and the cell dummy pad are discontinuously disposed along a boundary between the chip region and the guard ring region.

15. The semiconductor device according to claim 12, wherein a width of the top surface of the ferry dummy pad is the same as a width of a bottom surface of the cell dummy pad.

16. The semiconductor device according to claim 12, wherein the scribe lane test pad is disposed closer to the guard ring region than the cell dummy pad.

17. A semiconductor device comprising:
a substrate including a chip region, a guard ring region positioned outside and adjacent to the chip region, and a scribe lane region positioned adjacent to the guard ring region;
a cell test pad disposed across the guard ring region and the scribe lane region; and
a ferry test pad disposed in the guard ring region and positioned below the cell test pad.

18. The semiconductor device according to claim 17, further comprising a scribe lane test pad disposed in the scribe lane region and positioned below the cell test pad.

19. The semiconductor device according to claim 17, further comprising:
a cell dummy pad disposed in the scribe lane region and spaced apart from the cell test pad; and
a ferry dummy pad positioned below the cell dummy pad.

20. A partitionability monitoring method of a semiconductor device comprising:
a cell test pad disposed in a guard ring region;
a scribe lane test pad disposed in a scribe lane region continuously located from the guard ring region; and
a ferry test pad connected to the cell test pad and the scribe lane test pad, the method comprising:
applying a voltage to the scribe lane test pad; and
measuring a current flowing between the cell test pad and the scribe lane test pad to determine the straightness of the division.
